(19) United States
(12) Patent Application Publication
(10) Pub. No.: US 2006/0170047 A1
(43) Pub. Date: Aug. 3, 2006

(54) Semiconductor device and method of manufacturing the same

(75) Inventor: Kazunari Ishimaru, Yokohama-Shi (JP)

Correspondence Address: FOLEY AND LARDNER LLP;SUITE 500, 3000 K STREET NW, WASHINGTON, DC, 20007, US

(73) Assignee: KABUSHIKI KAISHA TOSHIBA

(21) Appl. No.: 11/297,636

(22) Filed: Dec. 9, 2005

(30) Foreign Application Priority Data
Dec. 10, 2004 (JP) 2004-357910

(51) Int. Cl. H01L 27/12

(52) U.S. Cl. 257/347

(57) ABSTRACT

A semiconductor device according to an embodiment of the present invention comprises a semiconductor substrate; and a plurality of MOSFETs which are formed on the semiconductor substrate, are the same conductivity type, and have gate insulating films of the same insulating material, with each gate insulating film having any one of a plurality of different thicknesses, and wherein a gate electrode of the MOSFET having a first gate insulating film of a small thickness, consisting substantially of silicide, and a gate electrode of a MOSFET having a second gate insulating film of a thickness larger than that of the first gate insulating film has a structure consisting of polycrystalline silicon, amorphous silicon or silicon-germanium and silicide formed on the polycrystalline silicon, amorphous silicon or germanium silicon.

### CROSS-REFERENCE TO RELATED APPLICATION

This application is based upon and claims the benefit of priority from the prior Japanese Patent Applications No. 2004-357910, filed on Dec. 10, 2004, the entire contents of which are incorporated herein by reference.

### BACKGROUND OF THE INVENTION

1. Field of the Invention

The present invention relates to a semiconductor device and, more particularly, to a structure of a gate electrode and a gate insulating film constituting a MOSFET formed on a semiconductor substrate and a method of manufacturing a semiconductor device.

2. Related Art

A MOSFET conventionally used in a semiconductor device is stationarily reduced in size to realize the high integration, low cost, and high performance of a semiconductor device. This reduction in size is also applied to not only a gate length or a gate insulating film, but also a junction depth of a diffusion layer such as a source/drain region according to a rule generally called a scaling rule. In order to make it possible to operation even though the gate length is reduced, not only a reduction in thickness of the gate insulating film but also a reduction in junction depth of a diffusion layer (swallowing) must be performed. The diffusion layer is generally formed by ion implantation and activating heat treatment. In order to reduce the junction depth, ion implantation energy must be reduced, and, at the same time, the heat treatment temperature must be lowered to suppress diffusion caused by the heat treatment. However, when the heat treatment temperature is lowered, the activation rate of an impurity disadvantageously decreases. In particular, when the activation rate of an impurity in the gate electrode decreases, a depletion layer is formed on the interface of the gate insulating film to increase the effective thickness of the gate insulating film, and the performance of the MOSFET is deteriorated. When the depletion layer is formed, the depletion layer functions as a gate insulating film. For this reason, the thickness of the depletion layer is added to the thickness (physical thickness) of the gate insulating film to obtain an apparent thickness.

This phenomenon occurs because the gate electrode material is a semiconductor. If the gate electrode material is a metal, the phenomenon does not occur. A metal gate electrode was used in the early stage of LSI development. An aluminum gate electrode or the like was used. However, the aluminum has a low heat resistance, cannot easily form a source/drain region in a self-aligning manner, is not oriented to micropatterning, so that the metal gate electrode is replaced with a polysilicon gate electrode.

In recent years, a system in which a gate electrode consisting of polycrystalline silicon is replaced by a method called a Damascene gate process after a source/drain region is formed is proposed (IEDM '98 (A. Yagishita, et. al) (FIG. 1)). In this method, a dummy gate structure is formed, and the dummy gate structure is covered with an insulating film and CMP-processed to expose the dummy gate. The dummy gate is removed to form a gate trench such that the semiconductor substrate is exposed. After a gate insulating film is formed on a semiconductor substrate surface in the gate trench, a metal for a gate material is deposited in the gate trench and on the insulating film. The deposited metal is CMP-processed to remove the metal on the insulating film, and the metal is buried in the gate trench. Use of this method makes it possible to avoid high-temperature heat treatment. However, the system is not oriented to micropatterning because the metal cannot easily bury the narrow trench.

Furthermore, a system which suicides an entire gate electrode part to obtain a metal gate is also proposed (IEDM '03 (J. Kedzierski, et. Al.) (FIG. 1)). This method is related to a semiconductor substrate having a fully depleted SOI (FDSOI: Fully Depleted Silicon On Insulator)). In the method, a gate side wall is formed on a polysilicon gate electrode. The gate electrode including the gate side wall is CMP-processed to expose a gate electrode. Nickel is brought into contact with the gate electrode to fully silicide the polycrystalline silicon of the gate electrode. According to the method, since all the gate electrodes consist of the metal, a threshold voltage cannot be easily controlled, and a high-voltage-operated MOSFET used in inputting/outputting (I/O) or the like is not especially considered at all. For this reason, a conventional technique cannot satisfy the demands of a circuit design or a system design that simultaneously mounts a low-voltage-operated MOSFET and a high-voltage-operated MOSFET on the same semiconductor substrate to set threshold voltages suitable for various circuit operations.

In addition, when a semiconductor device having a fully depleted (FD (Fully Depleted)-SOI) structure is used by advancing micropatterning of a MOSFET, a metal gate electrode having an energy gap close to an intermediate energy gap (Mid-gap) is desirably used as a gate electrode. However, as a MOSFET such as an input/output (I/O) or an analog circuit having a power supply voltage, a partially depleted (PD (Partially Depleted)-SOI) structure or a Bulk structure is desirably used. When a metal gate is applied to the MOSFET, a threshold voltage cannot be easily controlled.

A semiconductor device obtained by mounting a plurality of semiconductor elements having different operation voltages on one semiconductor substrate is as follows. That is, for example, a nitride film is formed on gate oxide film surfaces of a memory cell portion and a peripheral PMOS on the semiconductor substrate, a metal layer, a polycrystalline Si layer, and a silicide layer having work functions of 4.8 to 5.0 eV are used as a gate electrode of the memory cell portion, and an NMOS gate electrode of a peripheral circuit is constituted by a polycrystalline Si layer and a silicide layer (Japanese Patent Application Laid-open No. 2003-142601). Japanese Patent Application Laid-open No. 2002-359295 discloses a semiconductor device in which different insulating films are used in a PMOS of an NMOS of a CMOS device and metals having different work functions are used in a gate electrode. Japanese Patent Application Laid-open No. 2001-358225 discloses a semiconductor device in which a dual gate structure is constituted by a low-voltage operation region having a diffusion barrier layer and a high-voltage operation region having no diffusion barrier layer.

### SUMMARY OF THE INVENTION

A semiconductor device according to an embodiment of the present invention comprises a semiconductor substrate; and

a plurality of MOSFETs which are formed on the semiconductor substrate, are the same conductivity type, and have gate insulating films of the same insulating material, with each gate insulating film having any one of a plurality of different thicknesses, and wherein

a gate electrode of the MOSFET having a first gate insulating film of a small thickness, consisting substantially of silicide, and a gate electrode of a MOSFET having a second gate insulating film of a thickness larger than that of the first gate insulating film has a structure consisting of polycrystalline silicon, amorphous silicon or silicon-germanium and silicide formed on the polycrystalline silicon, amorphous silicon or germanium silicon.

A semiconductor device according to an embodiment of the present invention comprises a semiconductor substrate;

a first MOSFET comprising a first gate insulating film formed on the semiconductor substrate and further comprising a first gate electrode made of silicide on the first gate insulating film; and

a second MOSFET comprising a second gate insulating film formed on the semiconductor substrate and thicker than the first gate insulating film, and further comprising a second gate electrode formed on the second gate insulating film, a part of the second gate electrode, which partly contacts with at least the second gate insulating film, being made of polycrystalline silicon, amorphous silicon or silicon germanium.

A method of manufacturing a semiconductor device according to an embodiment of the present invention comprises forming an oxide film in a region for forming a thin gate insulating film and a region for forming a thick gate insulating film on a semiconductor substrate surface of a semiconductor substrate;

removing the oxide film in the region for forming the thin gate insulating film from the semiconductor substrate, forming a thin oxide film serving as a thin gate insulating film in the region, and increasing the thickness of the oxide film to make a thick gate oxide film;

depositing a polycrystalline silicon, amorphous silicon or silicon-germanium film on the semiconductor substrate;

depositing an insulating film on the polycrystalline silicon, amorphous silicon or silicon-germanium film;

removing the insulating film in the region for forming the thin gate insulating film;

patterning the polycrystalline silicon, amorphous silicon or silicon-germanium film and the insulating film thereon to form a gate electrode of polycrystalline silicon, amorphous silicon or silicon germanium in the region for forming the thin gate insulating film and to form a second gate electrode consisting of polycrystalline silicon, amorphous silicon or silicon germanium and covered with the insulating film in the region for forming the thick gate insulating film;

forming an impurity diffusion region serving as a source and drain region on the semiconductor substrate by using the first and second gate electrodes as masks;

depositing a first metal film on the semiconductor substrate to cover the insulating films formed on the first gate electrode and the second gate electrode;

performing heat treatment to the first metal film to silicide the surface of the impurity diffusion region and the surface of the first gate electrode;

depositing an insulating interlayer on the semiconductor substrate to cover the impurity diffusion region, the surface of which is silicided, the first gate electrode, the surface of which is silicided, and the second gate electrode the surface of which is covered with the insulating film;

CMP-processing the insulating interlayer to expose the surface of the first gate electrode, the surface of which is silicided, and removing the insulating film to expose the surface of the second gate electrode consisting of polycrystalline silicon;

depositing a second metal film on the polycrystalline silicon, amorphous silicon or silicon germanium of the first gate electrode, the surface of which is silicided, and the second gate electrode from which the insulating film is removed; and

substantially fully siliciding the polycrystalline silicon, amorphous silicon or silicon germanium of the first gate electrode, the surface of which is silicided, and partially siliciding the polycrystalline silicon, amorphous silicon or silicon germanium of the second gate electrode from which the insulating film is removed.

A method of manufacturing a semiconductor device according to an embodiment of the present invention, the semiconductor device comprises a first MOSFET including a first gate insulating film and a first gate electrode made of silicide; and a second MOSFET including a second gate insulating film thicker than the first gate insulating film and a second gate electrode, a part of the second gate electrode, which partly contacts with at least the second gate insulating film being made of polycrystalline silicon, amorphous silicon or silicon germanium,

forming an oxide film on the semiconductor substrate;

removing the oxide film in a first region forming the first MOSFET on the semiconductor substrate;

forming the first gate insulating film in the first region and forming the second gate insulating film by making thicker the oxide film in a second region forming the second MOSFET on the semiconductor substrate;

depositing a gate electrode material made of polycrystalline silicone, amorphous silicon or silicon germanium on the first and the second gate insulating films;

depositing a first insulating film material on the gate electrode material;

removing the first insulating film material above the first region;

patterning the gate electrode material and the first insulating film to form a first gate electrode pattern made of the first gate electrode material and to form a second gate electrode pattern made of the first gate electrode material and the first insulating film covering the first gate electrode material;

depositing a first metal film to cover the first and the second gate electrode patterns;

annealing the first metal film to silicide the upper part of the first gate electrode material of the first gate electrode pattern;

depositing an interlayer insulating film to cover the first and the second gate electrode patterns;

planarizing the interlayer insulating film to expose the upper surface of the silicided gate electrode material of the first gate electrode pattern and to expose the upper surface of the gate electrode material of the second gate electrode pattern;

depositing a second metal film on the first and the second gate electrode patterns;

annealing the second metal film to form the first gate electrode by substantially fully siliciding the gate electrode material of the first gate electrode pattern and to form the second gate electrode by partially siliciding the gate electrode material of the second gate electrode pattern.

### BRIEF DESCRIPTION OF THE DRAWINGS

FIGS. 1A and 1B are sectional views for explaining steps in manufacturing a semiconductor device according to a first embodiment of the invention;

FIGS. 2A and 2B are sectional views for explaining steps in manufacturing a semiconductor device according to a first embodiment of the invention;

FIGS. 3A and 3B are sectional views for explaining steps in manufacturing a semiconductor device according to a first embodiment of the invention;

FIG. 4 is sectional view for explaining steps in manufacturing a semiconductor device according to a first embodiment of the invention;

FIGS. 5A to 5C are sectional views for explaining steps in manufacturing a semiconductor device according to a second embodiment of the invention; and

FIGS. 6A and 6B are sectional views of a semiconductor device according to a third embodiment of the invention.

### DETAILED DESCRIPTION OF THE INVENTION

The present invention has the following characteristic feature. That is, in a semiconductor device in which a plurality of MOSFETs are simultaneously mounted on the same semiconductor substrate to cope with two or more different power supply voltages, a gate electrode of a (high-voltage) MOSFET having a thick gate insulating film (second gate insulating film) consists of polycrystalline or amorphous (Si) or silicon germanium (SiGe) on a side on which the gate electrode is in contact with the insulating film, and a gate electrode of a (low-voltage) MOSFET having a thin gate insulating film (first gate insulating film) consists of a material containing 1E¹⁸/cm³ of a metal on a side on which the gate electrode is in contact with the insulating film. More specifically, the low-voltage (LV) MOSFET uses a metal gate, and the high-voltage (HV) MOSFET uses a polysilicon or polysilicon-germanium gate.

Embodiments of the present invention will be described below.

### FIRST EMBODIMENT

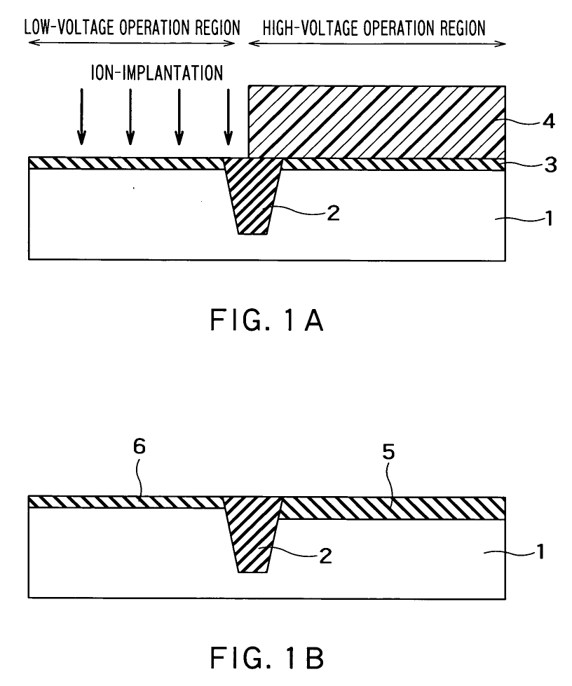

The first embodiment serving as one embodiment of the present invention will be described below with reference to the accompanying drawings, i.e., FIGS. 1A to 4.

FIGS. 1A to 4 are sectional views for explaining steps in manufacturing a semiconductor device according to the embodiment. A sacrificial oxide layer 3 having a thickness of about 1 to 10 nm is formed by an oxidizing process on a semiconductor substrate consisting of silicon, or the like and having an element isolation region 2 such as an STI (Shallow Trench Isolation) formed in a surface region. A predetermined element region is masked by a photoresist 4 to perform ion implantation, thereby forming a well region and adjusting a threshold voltage (FIG. 1A). The sacrificial oxide layer 3 is removed from the semiconductor substrate 1, and the semiconductor substrate 1 is applied with heat treatment again to form a silicon oxide film 5 having a thickness of about 0.1 to 10 nm and serving as a gate insulating film. The silicon oxide film 5 will serve as a thick gate insulating film (second gate insulating film) for a high-voltage operation MOSFET later. The silicon oxide film 5 is removed from a portion on which a thin gate insulating film (first gate insulating film) is to be formed, and a thin silicon oxide film 6 serving as a thin gate insulating film for a low-voltage MOSFET and being thinner than a thick gate insulating film having as a thickness of about 0.1 to 3 nm is formed (FIG. 1B).

At this time, nitrogen may be contained in the gate insulating film to reduce a gate leak current and to suppress an impurity from penetrating from the gate electrode to the semiconductor substrate. The density of the contained nitrogen is appropriately 5E20/cm³ or more. As a method of containing nitrogen, a gas containing nitrogen may be caused to flow in formation of an oxide film, or a process of nitriding an oxide film surface may be performed after an insulating film is formed. A change of this method does not lose the essence of the present invention.

The first and the second gate insulating films may be made from high-k (high dielectric constant) material, for example a silicate film including Hafnium (Hf).

Further, the thickness of the second gate insulating film (the high-voltage MOSFET) is thicker than that of the first gate insulating film (the low-voltage MOSFET). Here, the thicknesses may be compared as physical thicknesses, but they may be compared as EOT (Equivalent Oxide Thickness).

After the thin silicon oxide film 6 is formed, a polycrystalline silicon film 7 having a thickness of about 50 to 200 nm and serving as a gate electrode is deposited on the semiconductor substrate 1. Although the polycrystalline silicon film is deposited in the embodiment, an amorphous silicon film, a polycrystalline silicon (polycrystalline silicon-germanium) film containing germanium, a laminated structure including these films may be used.

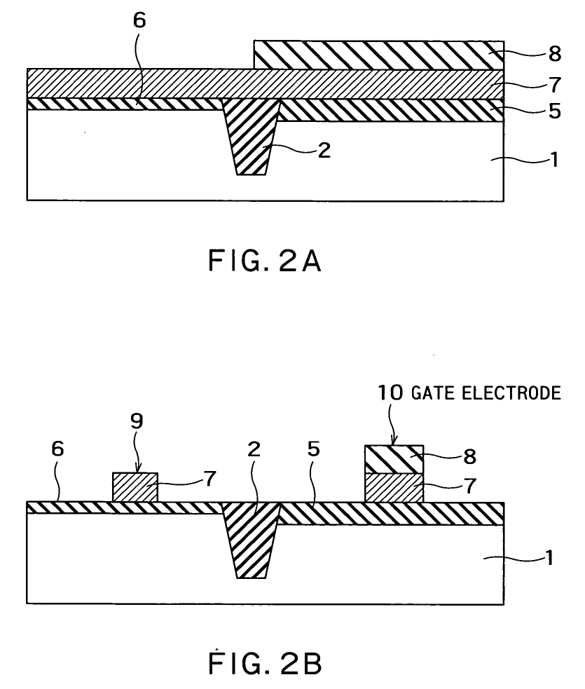

Thereafter, an insulating film 8 such as a silicon nitride film or a silicon oxide film having a thickness of about 10 to 200 nm is deposited on the polycrystalline silicon film 7. The insulating film 8 is removed by etching or the like from a portion where the low-voltage operation MOSFET forming region (to be referred to as a low-voltage operation region hereinafter) (FIG. 2A). Therefore, the insulating film 8 is formed in only the high-voltage operation MOSFET forming region (to be referred to as a high-voltage operation region hereinafter). The polycrystalline silicon film 7 and the insulating film 8 are patterned by using an ordinary photolithography technique to form a gate electrode 9 constituted by a polycrystalline silicon film in the low-voltage operation region and a gate electrode 10 constituted by a polycrystalline silicon film covered with the insulating film 8 in the high-voltage operation region (FIG. 2B). More specifically, at this time, only the high-voltage operation MOSFET having the thick gate insulating film has a structure in which the insulating film is laminated on the gate electrode. The gate electrode 9 contains 1E¹⁸/cm³ or more of at least one impurity selected from B, As, P, and Sb.

By using the gate electrodes 9 and 10 as masks, a shallow impurity diffusion region 11 is formed by a method such as ion implantation and thermal diffusion of impurity. Thereafter, side wall insulating films 12 and 13 such as silicon nitride films are formed on the sides of the gate electrodes 9 and 10. Thereafter, by using the side wall insulating films 12 and 13 as masks, a deep impurity diffusion region 14 is formed by a method such as ion implantation and thermal diffusion of an impurity. The shallow impurity diffusion region 11 and the deep impurity diffusion region 14 constitute a source/drain region of a MOSFET.

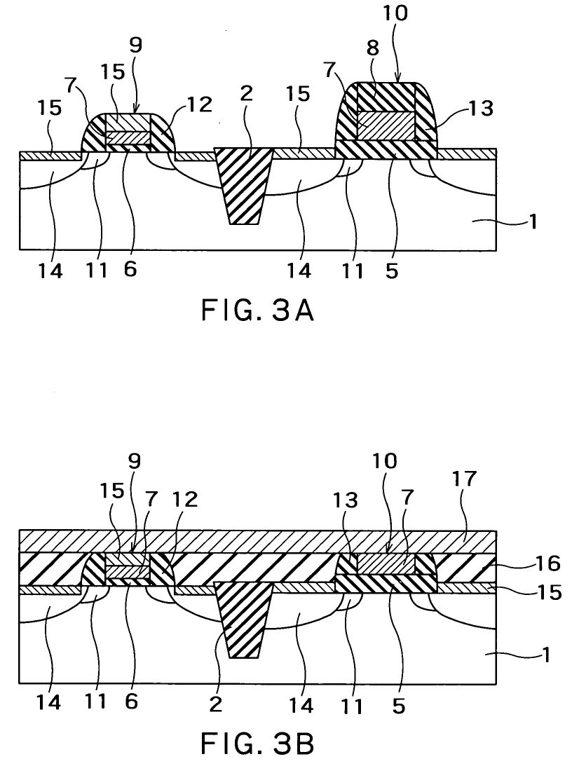

The silicon oxide films 5 and 6 are removed from the surface of the semiconductor substrate 1 except for a region in which the gate structure constituted by the gate electrodes and the side wall insulating films. Thereafter, metal films consisting of Ni, Pt, Ti, Co, or the like are deposited on the deep impurity diffusion region 14, the gate electrode 9, and the like on the surface of the semiconductor substrate 1 to have thicknesses of about 1 to 20 nm. The metal films are applied with heat treatment to form a silicide layer 15 on the deep impurity diffusion region 14 and the gate electrode 9 of the MOSFET having the thin gate insulating film (FIG. 3A). At this time, no silicide layer is formed on the gate electrode 10 of the MOSFET having the thick gate insulating film in the high voltage operation region because the gate electrode 10 is covered with the insulating film 8. In this embodiment, although Ni, Pt, Ti, or Co are used as examples of the metal for forming silicide, another material such as a metal film which can form silicide to obtain a necessary work function may be used. Even though the materials are changed, the effect of the present invention cannot be lost.

An insulating film 16 such as a silicon oxide film is deposited on the entire surface of the semiconductor substrate 1. The deposited insulating film 16 is removed by a planarizing process such as CMP (Chemical Mechanical Polishing) until the gate electrode of the MOSFET is exposed. At this time, the insulating film 8 on the gate electrode of the MOSFET having the thick gate insulating film is also removed. Thereafter, a metal film 17 consisting of Ni, Pt, Ti, Co, or the like to form a silicide layer is deposited again (FIG. 3B) to cause silicide reaction in only the gate electrode. At this time, the thickness of the metal film 17 to be deposited, a reaction heat treatment temperature, and heat treatment time are optimized, so that the gate electrode 10 of the MOSFET having the thick gate insulating film in the high-voltage operation region is not fully silicided to leave a polycrystalline silicon part. On the other hand, the gate electrode 9 of the MOSFET having the thin gate insulating film in the low-voltage operation region is fully silicided to form a silicide layer 15a. This is because the gate electrode of the MOSFET having the thin gate insulating film is fully silicided by a thinner metal film than a metal film which can fully silicide the gate electrode of the MOSFET having the thick gate insulating film, or this is because the gate electrode is fully silicided within time shorter than that of the MOSFET having the thick gate insulating film, since silicide is formed in the gate electrode of the MOSFET having the thin gate insulating film in advance. Therefore, the gate electrode 10 is constituted by the polycrystalline silicon film 7 and a silicide layer 7a formed thereon.

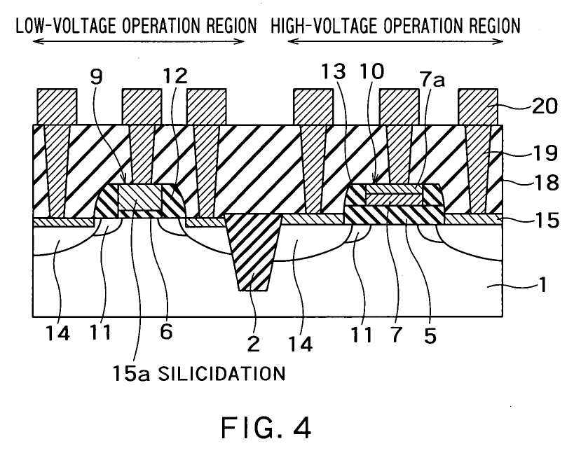

An insulating film 18 such as a silicon oxide film is deposited on the entire surface of the semiconductor substrate 1 to cover the MOSFET formed on the semiconductor substrate 1. The insulating film 18 is planarized, and contact holes are formed at predetermined positions by anisotropic etching such as RIE such that the silicide layer 15 formed on the gate electrodes 9 and 10 and the impurity diffusion region 14 is exposed. A metal such as tungsten is buried in the contact holes as connection wiring layers 19 to achieve connection to an external circuit. A wiring pattern 20 is forme on the surface of the planarized insulating film 18. The wiring pattern 20 includes external connection terminals to be electrically connected to the gate electrodes 9 and 10 and the impurity diffusion region 14 through the connection wiring layer 19. Thereafter, an ordinary MOSFET manufacturing process is performed to complete a semiconductor device (FIG. 4).

The embodiment makes it possible to provide optimum gate electrodes to a low-voltage operation MOSFET and a high-voltage operation MOSFET formed on one semiconductor substrate. The performance of the element can be prevented from being deteriorated by advancing of micropatterning. For example, on one silicon chip, a low-voltage operation MOSFET having a voltage of, e.g., about 1 to 1.2 V can be formed as a main circuit such as a logic circuit or a memory circuit, and a high-voltage operation MOSFET having a voltage of, e.g., about 2.5 to 3.3 V can be formed as a peripheral circuit such as an I/O. In addition, these MOSFETs can be formed under the optimum conditions described above.

### SECOND EMBODIMENT

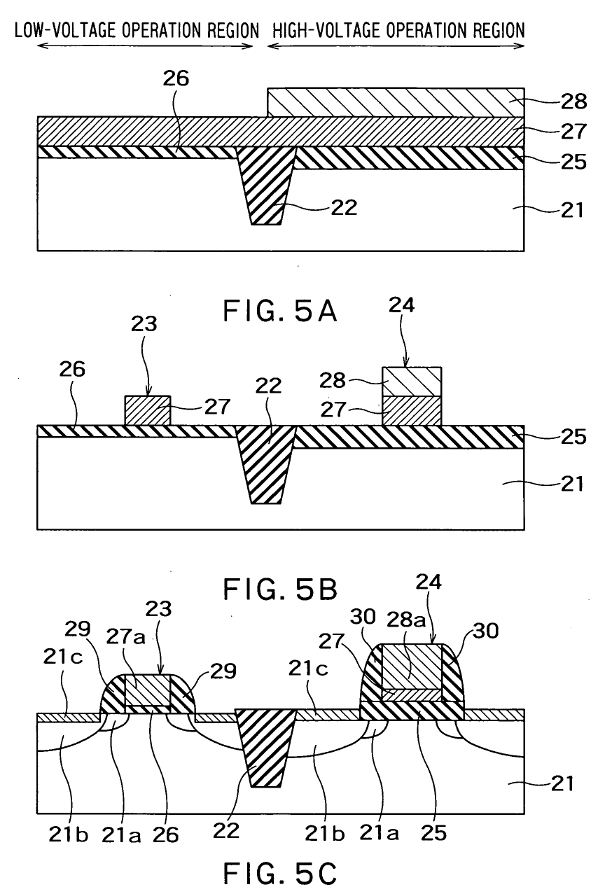

The second embodiment will be described below with reference to FIGS. 5A to 5C.

FIGS. 5A to 5C are sectional view for explaining steps in manufacturing a semiconductor device according to the embodiment. The embodiment has the following characteristic feature. That is, a film obtained by containing germanium in polycrystalline silicon and a polycrystalline silicon film are used as gate electrode materials. Depending on the thicknesses of these films, it is determined whether a gate electrode is fully silicided or partially silicided. In the embodiment, the same steps as those in the first embodiment are performed until the steps of forming a plurality of gate insulating films and depositing a polycrystalline silicon film serving as a gate electrode material.

On the surface of a semiconductor substrate 21 on which an element isolation region 22 such as STI is formed and which consists of silicon or the like, a silicon oxide film 26 having a thickness of about 0.1 to 3 nm and serving as a thin gate insulating film (first gate insulating film) is formed in a low-voltage operation region, a silicon oxide film 25 having a thickness of about 0.1 to 10 nm and serving as a thick gate insulating film (second gate insulating film) thicker than the thin gate insulating film is formed in a high-voltage operation region. After the silicon oxide film 26 is formed, a first polycrystalline silicon film 27 having a thickness of about 20 to 100 nm and serving as a gate electrode is deposited on the semiconductor substrate 21. Thereafter, a polycrystalline silicon-germanium film 28 having a thickness of about 20 to 100 nm is deposited on the polycrystalline silicon film 27. The polycrystalline silicon-germanium film 28 consists of a material expressed by general formula: SiₓGe₁₋ₓ (0<x<1). The density of Ge in the film is appropriately selected within the range of x. A part which covers the low-voltage operation region of the polycrystalline silicon-germanium film 28 is removed by etching or the like (FIG. 5A).

The polycrystalline silicon film 27 and the polycrystalline silicon-germanium film 28 are patterned by an ordinary photolithography technique to form a gate electrode 23 constituted by the polycrystalline silicon film 27 in the low-voltage operation region and a gate electrode 24 constituted by the polycrystalline silicon film 27 and the polycrystalline silicon-germanium film 28 formed thereon in the high-voltage operation region. More specifically, the gate electrode of the MOSFET having the thin gate insulating film in the low-voltage operation region is lower than the gate electrode of the MOSFET having the thick gate insulating film in the high-voltage operation region (FIG. 5B). In the embodiment, although the insulating film described in the first embodiment is not deposited on the gate electrode, the insulating film may be deposited if necessary. The effect of the present invention can be achieved regardless of the presence/absence of the insulating film on the gate electrode.

A shallow impurity diffusion region 21a is formed by a method such as ion implantation and thermal diffusion of an impurity using gate electrodes 23 and 24 as masks. Thereafter, side wall insulating films 29 and 30 such as silicon nitride films are formed on the sides of the gate electrodes 23 and 24. Thereafter, a deep impurity diffusion region 21b is formed by a method such as ion implantation or thermal diffusion of an impurity using the side wall insulating films 29 and 30 as masks. The shallow impurity diffusion region 21a and the deep impurity diffusion region 21b constitute source/drain regions of a MOSFET.

The silicon oxide films 25 and 26 are removed from the surface of the semiconductor substrate 21 except for a region in which a gate structure constituted by the gate insulating films, the gate electrodes, and the side wall insulating films is formed. A metal film consisting of Ni, Pt, Ti, or Co is deposited on the deep impurity diffusion region 21b and the gate electrodes 23 and 24 on the surface of the semiconductor substrate 21 and applied with heat treatment to form a silicide layer 21c on the deep impurity diffusion region 21b. The polycrystalline silicon film of the gate electrode 23 of the MOSFET having the thin gate insulating film in the low-voltage operation region is fully silicided, the polycrystalline silicon-germanium film and the polycrystalline silicon film constituting the gate electrode 24 of the MOSFET having the thick gate insulating film in the high-voltage operation region are partially silicided (silicide layers 27a and 28a), the polycrystalline silicon film 27 is not silicided at a portion where the polycrystalline silicon film 27 is in contact with the silicon oxide film 25 to leave the polycrystalline silicon film. The silicide layer 21c on the deep impurity diffusion region 21b consists of the same material as silicide constituting the gate electrode (FIG. 5C).

In this manner, in the embodiment, the MOSFET having the thin gate insulating film has the gate electrode thicker than the gate electrode of the MOSFET having the thick gate insulating film. For this reason, even though a silicide process is ordinarily performed, the gate electrode of the MOSFET having the thin gate insulating film is fully silicided in advance. The thickness of the metal film to be deposited, a heat treatment temperature, and heat treatment time are optimized to make it possible to achieve a process having a sufficient margin. Furthermore, according to the embodiment, since the step (see FIG. 3B) of exposing the upper part of the gate electrode by planarization as in the first embodiment is unnecessary, the steps are simplified.

### THIRD EMBODIMENT

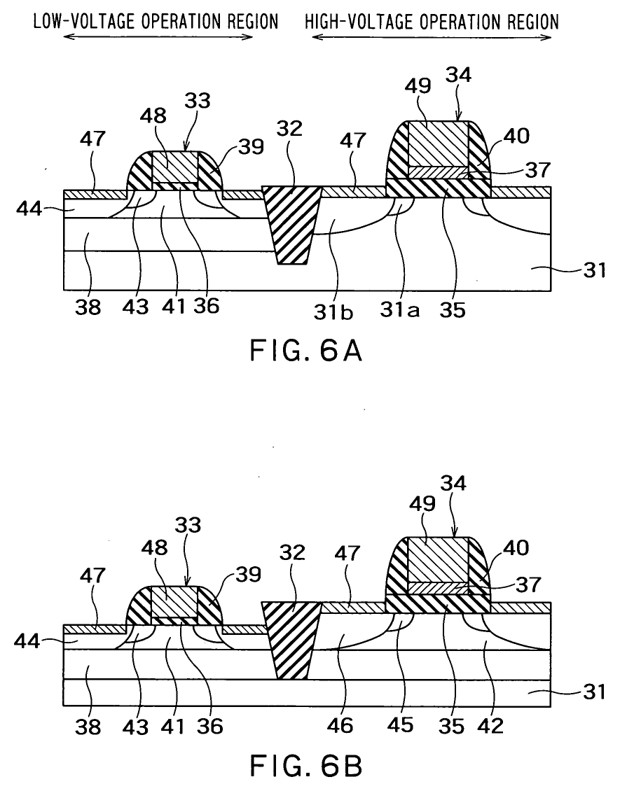

The third embodiment will be described below with reference to FIGS. 6A and 6B.

FIGS. 6A and 6B are sectional views for explaining a semiconductor device. The embodiment has a characteristic feature in which a MOSFET is formed on a partial SOI substrate. In a semiconductor device shown in FIG. 6A, a partial SOI substrate is formed in a low-voltage operation region. An element isolation region 32 such as an STI is formed in a surface region of a semiconductor substrate 31 consisting of silicon or the like, a MOSFET having a thin gate insulating film (first gate insulating film) on the partial SOI substrate is formed in the low-voltage operation region, and a MOSFET having a thick gate insulating film (second gate insulating film) thicker than the thin gate insulating film is formed on an ordinary bulk substrate.

The partial SOI substrate in the low-voltage operation region is constituted by an insulating layer 38 such as a silicon oxide film formed on the semiconductor substrate 31 and a silicon epitaxial layer 41 formed thereon. A pair of a shallow impurity diffusion region 43 and a deep impurity diffusion region 44 constituting source/drain regions are formed on the silicon epitaxial layer 41, a thin gate insulating film 36 constituted by a silicon oxide film having a thickness of about 0.1 to 3 nm is formed on a portion between the impurity diffusion regions, and a gate electrode 33 constituted by a silicide layer 48 containing a metal selected from Ni, Pt, Ti, Co, and the like is formed on the thin gate insulating film 36. A side wall insulating film 39 constituted by a silicon nitride film or the like is formed on a side surface (side) of the gate electrode 33. A suicide layer 47 consisting of the same material as silicide of the gate electrode is formed in the deep impurity diffusion region 44.

A shallow impurity diffusion region 31a and a deep impurity diffusion region 31b constituting source/drain regions are formed in the high-voltage operation region, and a thick gate insulating film 35 thicker than the thin gate insulating film 36 and constituted by a silicon oxide film having a thickness of about 01 to 10 nm is formed on a portion between the impurity diffusion regions, and a gate electrode 34 constituted by a polycrystalline silicon film 37 and a silicide layer 49 formed on the polycrystalline silicon film 37 and containing a metal selected from Ni, Pt, Ti, Co, and the like is formed on the thick gate insulating film 35. On the side surface (side) of the gate electrode 34, a side wall insulating film 40 such as a silicon nitride film is formed. The silicide layer 47 consisting of the same material as that of the silicide layer of the gate electrode 34 is formed on the deep impurity diffusion region 31b.

In the semiconductor device shown in FIG. 6B, partial SOI substrates are formed in the low-voltage operation region and the high-voltage operation region. The element isolation region 32 such as an STI is formed in the surface region of the semiconductor substrate 31 consisting of silicon or the like, and MOSFETs are formed on the partial SOI substrates in the low-voltage operation region and the high-voltage operation region, respectively.

The SOI substrate in the low-voltage operation region has the same structure as that in FIG. 6A.

The SOI substrate in the high-voltage operation region is constituted by the insulating layer 38 such as a silicon oxide film formed on the semiconductor substrate 31 and a silicon epitaxial layer 42 formed on the insulating layer 38. The epitaxial layer 42 is deposited to have a thickness larger than that of the epitaxial layer 41 in the low-voltage operation region. A shallow impurity diffusion region 45 and a deep impurity diffusion region 46 constituting source/drain regions are formed on the epitaxial layer 42, and the thick gate insulating film 35 having a thickness larger than that of the thin gate insulating film 36 and constituted by a silicon oxide film having a thickness of about 0.1 to 10 nm is formed on a portion between the impurity diffusion regions, and the gate electrode 34 constituted by the polycrystalline silicon film 37 and the silicide layer 49 formed on the polycrystalline silicon film 37 and containing a metal selected from Ni, Pt, Ti, Co, and the like is formed on the thick gate insulating film 35. The side wall insulating film 40 such as a silicon nitride film is formed on a side surface (side) of the gate electrode 34. The silicide layer 47 consisting of the same material as that of the silicide layers 48 and 49 of the gate electrode is formed on the shallow impurity diffusion region 45.

In this embodiment, in the step of siliciding the gate electrode, any one of the methods explained in the first and second embodiments may be used. The MOSFETs on the partial SOI substrates may be of a partial depletion type or of a full depletion type. However, the full depletion type MOSFET is desirably used to obtain a stable threshold voltage. When the full depletion type MOSFET is used, the gate electrode desirably has a work function close to Mid-gap, and the work function can be easily realized in the embodiment. In a peripheral circuit such as an I/O unit, since an operation at a higher power supply voltage and a plurality of threshold voltages are necessary, a conventional polycrystalline-silicon-based gate electrode is used conveniently more than a metal gate electrode.

According to the embodiment, MOSFETs which are optimized for different power supply voltages can be provided at low cost. A MOSFET having a thick gate insulating film used at a high power supply voltage may be used as a partial depletion type SOI substrate. With this configuration, the parasitic capacitance of the impurity diffusion region is reduced to make it possible to operate the semiconductor device at a speed higher than that of a conventional semiconductor device.

As described above, nitrogen is added to a gate insulating film constituting the MOSFET according to the present invention, and a peak nitrogen concentration in a first gate insulating film can be made higher than a peak nitrogen concentration in a second gate insulating film. According to the present invention, a silicide layer is formed on a diffusion layer constituting a MOSFET, the same material can be used as the material of silicide fully or partially constituting a gate electrode and the material of a silicide layer formed on the diffusion layer. Furthermore, according to the present invention, the gate length of a MOSFET having a first gate insulating film can be made shorter than the gate length of a MOSFET having a second gate insulating film. According to the present invention, a MOSFET having the first gate insulating film has an SOI structure formed on a silicon single-crystal layer on an oxide layer formed on a semiconductor substrate, and the other MOSFET having a gate electrode which is not fully silicided can be formed on the semiconductor substrate. According to the present invention, the gate electrode of the MOSFET having the gate electrode which is fully silicided can be made lower than the gate electrode of the MOSFET having the gate electrode which is not fully silicided. According to the present invention, the first gate insulating film can be formed such that at least metal atoms are present in a density of 1E¹⁹/cm³ or more on an interface opposing the semiconductor substrate. In addition, according to the present invention, metal atoms can be present at 1E¹⁷/cm³ or less on the interface on the upper part of the second gate insulating film.

What is claimed is:

1. A semiconductor device comprising:
a semiconductor substrate; and
a plurality of MOSFETs which are formed on the semiconductor substrate, are the same conductivity type, and have gate insulating films of the same insulating material, with each gate insulating film having any one of a plurality of different thicknesses, and wherein
a gate electrode of the MOSFET having a first gate insulating film of a small thickness, consisting substantially of silicide, and a gate electrode of a MOSFET having a second gate insulating film of a thickness larger than that of the first gate insulating film has a structure consisting of polycrystalline silicon, amorphous silicon or silicon-germanium and silicide formed on the polycrystalline silicon, amorphous silicon or germanium silicon.

2. The semiconductor device according to claim 1, wherein nitrogen is added to the gate insulating film, and a total nitrogen content in the first gate insulating film is larger than a total nitrogen content in the second gate insulating film.

3. The semiconductor device according to claim 2, wherein the MOSFET having the first gate insulating film has a full depletion-type SOI structure, and the MOSFET having the second gate insulating film has a partial depletion-type SOI structure.

4. The semiconductor device according to claim 2, wherein the MOSFET having the first gate insulating film has a full depletion-type SOI structure, and the MOSFET having the second gate insulating film has a partial depletion-type SOI structure.

5. The semiconductor device according to claim 1, wherein the gate electrode of the MOSFET having the first gate insulating film contains 1×10¹⁸/cm³ or more of at least one impurity selected from B, As, P, and Sb.

6. The semiconductor device according to claim 2, wherein the gate electrode of the MOSFET having the first gate insulating film contains 1×10¹⁸/cm³ or more of at least one impurity selected from B, As, P, and Sb.

7. The semiconductor device according to claim 3, wherein the gate electrode of the MOSFET having the first gate insulating film contains 1×10¹⁸/cm³ or more of at least one impurity selected from B, As, P, and Sb.

8. The semiconductor device according to claim 1, wherein the silicide contains any of Ni, Pt, Ti or Co.

9. A semiconductor device comprising:
a semiconductor substrate;
a first MOSFET comprising a first gate insulating film formed on the semiconductor substrate and further comprising a first gate electrode made of silicide on the first gate insulating film; and
a second MOSFET comprising a second gate insulating film formed on the semiconductor substrate and thicker than the first gate insulating film, and further comprising a second gate electrode formed on the second gate insulating film, a part of the second gate electrode, which partly contacts with at least the second gate insulating film, being made of polycrystalline silicon, amorphous silicon or silicon germanium.

10. The semiconductor device according to claim 9, wherein nitrogen is added to the gate insulating film, and a total nitrogen content in the first gate insulating film is larger than a total nitrogen content in the second gate insulating film.

11. The semiconductor device according to claim 9, wherein the first MOSFET has a full depletion type SOI structure, and the second MOSFET has a partial depletion type SOI structure.

12. The semiconductor device according to claim 9, wherein the first gate electrode contains 1×10¹⁸/cm³ or more of at least one impurity selected from B, As, P, and Sb.

13. The semiconductor device according to claim 9, wherein the suicide contains any of Ni, Pt, Ti or Co.

14. A method of manufacturing a semiconductor device comprising:
forming an oxide film in a region for forming a thin gate insulating film and a region for forming a thick gate insulating film on a semiconductor substrate surface of a semiconductor substrate;
removing the oxide film in the region for forming the thin gate insulating film from the semiconductor substrate, forming a thin oxide film serving as a thin gate insulating film in the region, and increasing the thickness of the oxide film to make a thick gate oxide film;
depositing a polycrystalline silicon, amorphous silicon or silicon-germanium film on the semiconductor substrate;
depositing an insulating film on the polycrystalline silicon, amorphous silicon or silicon-germanium film;
removing the insulating film in the region for forming the thin gate insulating film;
patterning the polycrystalline silicon, amorphous silicon or silicon-germanium film and the insulating film thereon to form a gate electrode of polycrystalline silicon, amorphous silicon or silicon germanium in the region for forming the thin gate insulating film and to form a second gate electrode consisting of polycrystalline silicon, amorphous silicon or silicon germanium and covered with the insulating film in the region for forming the thick gate insulating film;
forming an impurity diffusion region serving as a source and drain region on the semiconductor substrate by using the first and second gate electrodes as masks;
depositing a first metal film on the semiconductor substrate to cover the insulating films formed on the first gate electrode and the second gate electrode;
performing heat treatment to the first metal film to silicide the surface of the impurity diffusion region and the surface of the first gate electrode;
depositing an insulating interlayer on the semiconductor substrate to cover the impurity diffusion region, the surface of which is silicided, the first gate electrode, the surface of which is silicided, and the second gate electrode the surface of which is covered with the insulating film;
CMP-processing the insulating interlayer to expose the surface of the first gate electrode, the surface of which is silicided, and removing the insulating film to expose the surface of the second gate electrode consisting of polycrystalline silicon;
depositing a second metal film on the polycrystalline silicon, amorphous silicon or silicon germanium of the first gate electrode, the surface of which is silicided, and the second gate electrode from which the insulating film is removed; and
substantially fully siliciding the polycrystalline silicon, amorphous silicon or silicon germanium of the first gate electrode, the surface of which is silicided, and partially siliciding the polycrystalline silicon, amorphous silicon or silicon germanium of the second gate electrode from which the insulating film is removed.

15. The method of manufacturing a semiconductor device according to claim 14 further comprising:
adding nitrogen to the first and the second gate insulating films, so that a total nitrogen content in the first gate insulating film is larger than a total nitrogen content in the second gate insulating film.

16. The method of manufacturing a semiconductor device according to claim 14, wherein the first metal film and the second metal film are Ni, Pt, Ti or Co.

17. A method of manufacturing a semiconductor device which comprises a first MOSFET including a first gate insulating film and a first gate electrode made of silicide; and a second MOSFET including a second gate insulating film thicker than the first gate insulating film and a second gate electrode, a part of the second gate electrode, which partly contacts with at least the second gate insulating film being made of polycrystalline silicon, amorphous silicon or silicon germanium,
the method comprising:
forming an oxide film on the semiconductor substrate;
removing the oxide film in a first region forming the first MOSFET on the semiconductor substrate;
forming the first gate insulating film in the first region and forming the second gate insulating film by making thicker the oxide film in a second region forming the second MOSFET on the semiconductor substrate;
depositing a gate electrode material made of polycrystalline silicone, amorphous silicon or silicon germanium on the first and the second gate insulating films;
depositing a first insulating film material on the gate electrode material;
removing the first insulating film material above the first region;
patterning the gate electrode material and the first insulating film to form a first gate electrode pattern made of the first gate electrode material and to form a second gate electrode pattern made of the first gate electrode material and the first insulating film covering the first gate electrode material;
depositing a first metal film to cover the first and the second gate electrode patterns;
annealing the first metal film to silicide the upper part of the first gate electrode material of the first gate electrode pattern;
depositing an interlayer insulating film to cover the first and the second gate electrode patterns;
planarizing the interlayer insulating film to expose the upper surface of the silicided gate electrode material of the first gate electrode pattern and to expose the upper surface of the gate electrode material of the second gate electrode pattern;
depositing a second metal film on the first and the second gate electrode patterns;
annealing the second metal film to form the first gate electrode by substantially fully siliciding the gate electrode material of the first gate electrode pattern and to form the second gate electrode by partially siliciding the gate electrode material of the second gate electrode pattern.

18. The method of manufacturing a semiconductor device according to claim 17 further comprising:
forming a source region and a drain region on the semiconductor substrate using the first and the second gate electrode pattern as masks;
siliciding the surface of the source and the drain regions when the upper part of the gate electrode material of the first gate electrode pattern is silicided.

19. The method of manufacturing a semiconductor device according to claim 17 further comprising:
adding nitrogen to the first and the second gate insulating films, so that a total nitrogen content in the first gate insulating film is larger than a total nitrogen content in the second gate insulating film.

20. The method of manufacturing a semiconductor device according to claim 17, wherein the first metal film and the second metal film are Ni, Pt, Ti or Co.
